(19) United States
(12) Patent Application Publication
(10) Pub. No.: US 2025/0233078 A1
(43) Pub. Date: Jul. 17, 2025

(54) MULTI-LAYER ALIGNMENT MARK STRUCTURE

(71) Applicant: Taiwan Semiconductor Manufacturing Company, Ltd., Hsinchu (TW)

(72) Inventors: Tzu-Wei YU, Tainan (TW); Yeong-Jyh LIN, Tainan (TW); Kuan-Liang LIU, Tainan (TW); Ching I LI, Tainan (TW); Ching-Hung WANG, Tainan (TW)

(21) Appl. No.: 18/410,813

(22) Filed: Jan. 11, 2024

(51) Int. Cl. H01L 23/544; H01L 21/768; H01L 23/00; H01L 23/522

(52) U.S. Cl. CPC H01L 23/544; H01L 21/768; H01L 23/5226; H01L 24/05; H01L 2223/54426; H01L 2224/05

(57) ABSTRACT

Some implementations herein provide a semiconductor substrate including a multi-layer alignment mark structure and methods of formation. The multi-layer alignment mark structure may include concentric rings (e.g., a multi-ring bond mark structure) and a dummy pad structure below the concentric rings. For a light source of a given wavelength, the dummy pad structure may create an optical contrast between the concentric rings and annular regions of a dielectric region in which the concentric rings are formed. The optical contrast may improve a detectability of the multi-layer alignment mark structure by an automated optical inspection system relative to another alignment mark structure not including the dummy pad structure. The improved detectability, may in turn, reduce an amount of recognition errors by the automated optical inspection system detecting the multi-layer alignment mark structure to improve an efficiency of a semiconductor processing tool including the automated optical inspection system.

### BACKGROUND

Various semiconductor device packing techniques may be used to incorporate a semiconductor dies into a semiconductor die package. In some cases, semiconductor dies may be stacked in a semiconductor die package to achieve a smaller horizontal or lateral footprint of the semiconductor die package and/or to increase the density of the semiconductor die package. Semiconductor device packing techniques that may be performed to integrate a plurality of semiconductor dies in a semiconductor die package may include integrated fanout (InFO), package on package (PoP), chip on wafer (CoW), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example implementation of formation of a stacked die product described herein.

FIG. 3 is a diagram of an example multi-layer alignment mark structure described herein.

FIGS. 4A-4J are diagrams of an example series of semiconductor processing operations used to fabricate one or more portions of a multi-layer alignment mark structure described herein.

FIGS. 5A-5E are diagrams of example series of operations performed by a semiconductor processing tool using a multi-layer alignment mark structure described herein.

FIG. 6 is a diagram of example reflectance data for materials included in a multi-layer alignment mark structure described herein.

FIG. 7 is a diagram of example components of a device that may use a multi-layer alignment mark structure for an alignment operation.

FIGS. 8 and 9 are flowcharts of example processes related to a multi-layer alignment mark structure described herein.

FIGS. 10A and 10B are diagrams of example implementations of a multi-layer alignment mark structure described herein.

### DETAILED DESCRIPTION

The following disclosure provides many different embodiments, or examples, for implementing different features of the provided subject matter. Specific examples of components and implementations are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor substrate includes alignment mark structures. The alignment mark structures may aid alignment of the semiconductor substrate within a semiconductor processing tool for a semiconductor processing operation. The semiconductor processing operation may include joining bond pads of semiconductor dies included on separate semiconductor substrates as part of a semiconductor die stacking process (e.g., a wafer-on-wafer (WoW) stacking process), forming interconnects (e.g., wire bonds, stud bumps, solder balls) on pads of semiconductor dies included on the semiconductor substrate, or performing electrical tests on test pads (e.g., probe the test pads) of semiconductor dies included on the semiconductor substrate, or among other examples.

Recognition of the multi-layer alignment mark structures by an automated optical inspection (AOI) system included on the semiconductor processing tool can directly impact an efficiency of the semiconductor processing tool. If the multi-layer alignment mark structures are not recognizable on a repeatable basis, the efficiency of the semiconductor processing tool may be reduced, which may increase manufacturing costs and/or the amount of resources (e.g., an amount of the semiconductor processing tools, labor, and/or computing resources) needed to process a volume of semiconductor substrates.

Some implementations herein provide a semiconductor substrate including a multi-layer alignment mark structure and methods of formation. The multi-layer alignment mark structure may include concentric rings (e.g., a multi-ring bond mark structure) and a dummy pad structure below the concentric rings. For a light source of a given wavelength, the dummy pad structure may create an optical contrast between the concentric rings and annular regions of a dielectric region in which the concentric rings are formed. The optical contrast may improve a detectability of the multi-layer alignment mark structure by an AOI system relative to another alignment mark structure not including the dummy pad structure.

In this way, an efficiency of a semiconductor processing tool including the AOI system is increased. By increasing the efficiency of the semiconductor processing tool, an amount of resources needed to fabricate a volume of semiconductor substrates including the multi-layer alignment mark structure (e.g., a quantity of the semiconductor processing tool, labor, and/or computing resources) is reduced.

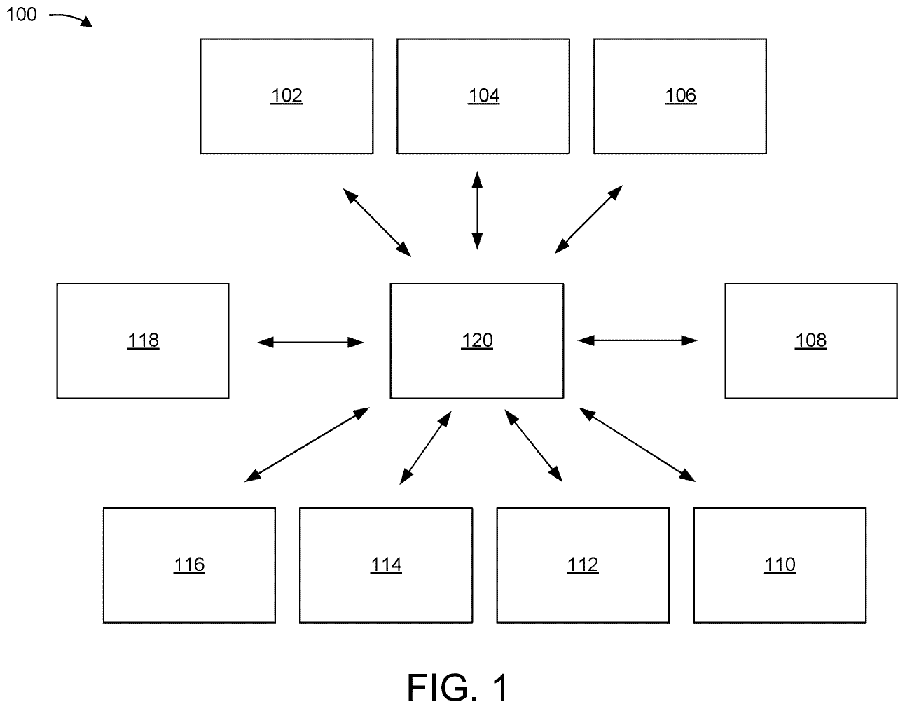

FIG. 1 is a diagram of an example environment 100 in which systems and/or methods described herein may be implemented. As shown in FIG. 1, environment 100 includes a combination of semiconductor processing tools, including a deposition tool 102, an exposure tool 104, an etch tool 106, a bonding tool 108, a dispense tool 110, a planarization tool 112, a connection tool 114, an automated test equipment (ATE) tool 116, a singulation tool 118, and a transport tool 120. The semiconductor processing tools 102-118 of example environment 100 may be included in a facility such as a semiconductor clean or semi-clean room, a semiconductor foundry, a semiconductor processing facility, an outsourced assembly and test (OSAT) facility, and/or a manufacturing facility, among other examples.

The deposition tool 102 is a semiconductor processing tool that is capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV (EUV) light source, and/or the like), an x-ray source, an electron beam source, and/or another type of radiation source. The exposure tool 104 may expose a photoresist layer to the radiation source to transfer a pattern from a photomask to the photoresist layer. The pattern may include a pattern for forming semiconductor devices, may include a pattern for forming structures of a semiconductor device, may include a pattern for etching various portions of a semiconductor device, and/or the like. In some implementations, the exposure tool 104 includes a scanner, a stepper, or a similar type of exposure tool.

The etch tool 106 is a semiconductor processing tool that is capable of etching various types of materials of a substrate, wafer, or semiconductor device. For example, the etch tool 106 may include a wet etching tool, a dry etching tool, and/or another type of etching tool. A wet etching tool may include a chemical etching tool or another type of wet etching tool that includes a chamber filled with an etchant. The substrate may be placed in the chamber for a particular time period to remove particular amounts of a portions of the substrate. A dry etching tool may include a plasma etching tool, a laser etching tool, a reactive ion etching tool, or a vapor phase etching tool, among other examples. A dry etching tool may remove portions of the substrate using a sputtering technique, a plasma-assisted etch technique (e.g., a plasma sputtering technique or another type of technique involving the use of an ionized gas to isotropically or directionally etch the portions), or another type of dry etching technique.

The bonding tool 108 is a semiconductor processing tool that is capable of bonding two or more wafers (or two or more semiconductor substrates, or two or more semiconductor devices) together. For example, the bonding tool 108 may include a eutectic bonding tool that is capable of forming a eutectic bond between two or more wafers. In these examples, the bonding tool 108 may heat the two or more wafers to form a eutectic system between the materials of the two or more wafers.

The dispense tool 110 may dispense materials during fabrication of a semiconductor device. For example, the dispense tool 110 may include a pressurized jet nozzle that dispenses a polymer material between beveled edges of semiconductor substrates (e.g., wafers) as part of a multi semiconductor substrate stacking process.

The planarization tool 112 is a semiconductor processing tool that is capable of polishing or planarizing various layers of a wafer or semiconductor device. For example, the planarization tool 112 may include a chemical mechanical planarization (CMP) tool and/or another type of planarization tool that polishes or planarizes a layer or surface of deposited or plated material. The planarization tool may polish or planarize a surface of a semiconductor device with a combination of chemical and mechanical forces (e.g., chemical etching and free abrasive polishing). The planarization tool 112 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The connection tool 114 is a semiconductor processing tool that is capable of forming connection structures (e.g., electrically-conductive structures). The connection structures formed by the connection tool 114 may include a wire, a stud, a pillar, a bump, or a solder ball, among other examples. The connection structures formed by the connection tool 114 may include materials such as a gold (Au) material, a copper (Cu) material, a silver (Ag) material, a nickel (Ni) material, a tin (Sn) material, or a palladium (Pd) material, among other examples. The connection tool 114 may include a bumping tool, a wire-bond tool, or a plating tool, among other examples.

The ATE tool 116 is a semiconductor processing tool that is capable of testing a quality and a reliability of a integrated circuit dies and/or a semiconductor package (e.g., the integrated circuit dies after encapsulation). The ATE tool 116 may perform wafer testing operations, known good die (KGD) testing operations, and/or semiconductor die package testing operations, among other examples. The ATE tool 116 may include a parametric tester tool, a speed tester tool, and/or a burn-in tool, among other examples. Additionally, or alternatively, the ATE tool 116 may include a prober tool and/or probe card tooling, among other examples.

The singulation tool 118 is a semiconductor processing tool that is capable of singulating (e.g., separating, removing) integrated circuit dies from a wafer. For example, the singulation tool 118 may include a dicing tool, a sawing tool, and/or or a laser tool that cuts the integrated circuit dies from the wafer, among other examples.

The transport tool 120 is a semiconductor processing tool capable of transporting work-in-process (WIP) between the semiconductor processing tools 102-118. The transport tool 120 may be configured to accommodate a transport carriers such a wafer transport carrier (e.g., a wafer cassette or a front opening unified pod (FOUP), among other examples), a die carrier transport carrier (e.g., a film frame, among other examples), and/or a package transport carrier (e.g., a joint electron device engineering (JEDEC) tray or a carrier tape reel, among other examples). The transport tool 120 may also be configured to transfer and/or combine WIP amongst transport carriers. The transport tool 120 may include a pick-and-place tool, a conveyor tool, a robot arm tool, an overhead hoist transport (OHT) tool, an automated materially handling system (AMHS) tool, and/or another type of tool. In some implementations, the example environment 100 includes a plurality of types of such tools as part of the transport tool 120.

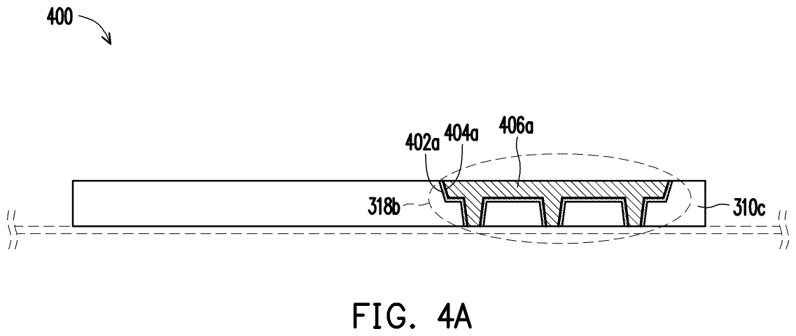

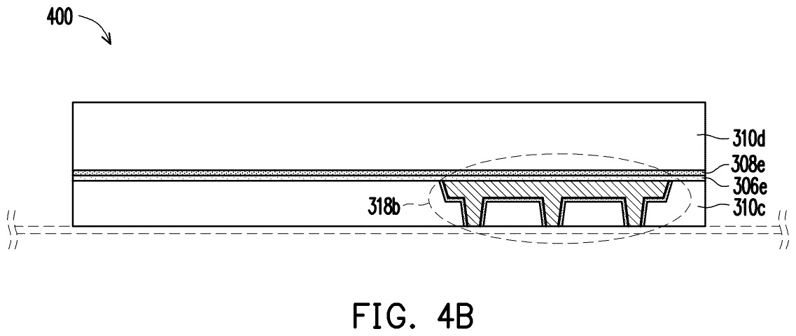

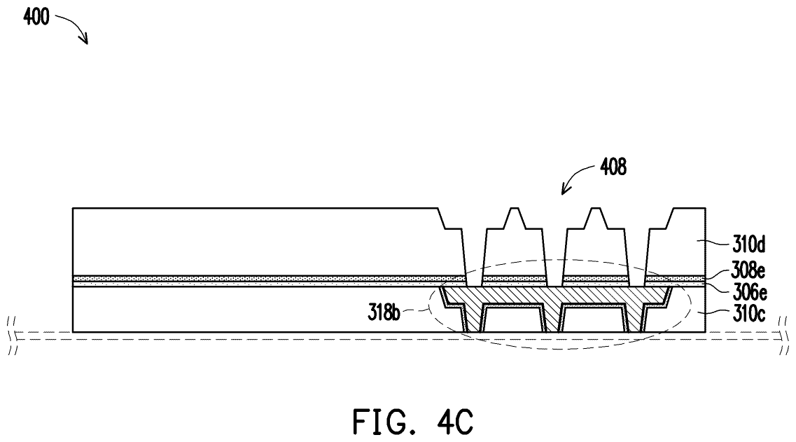

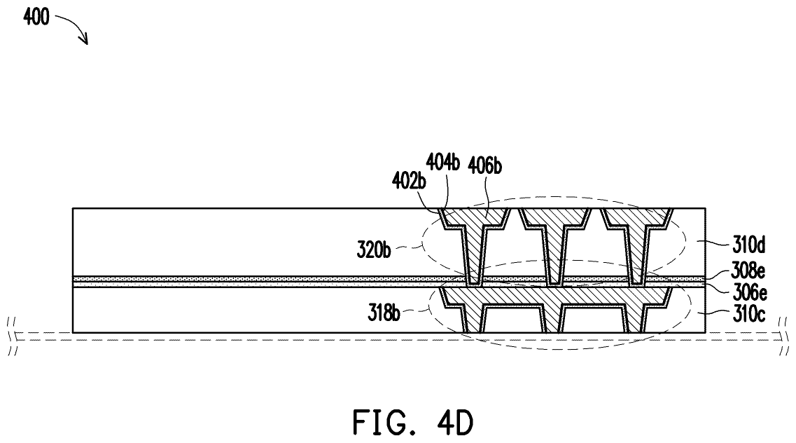

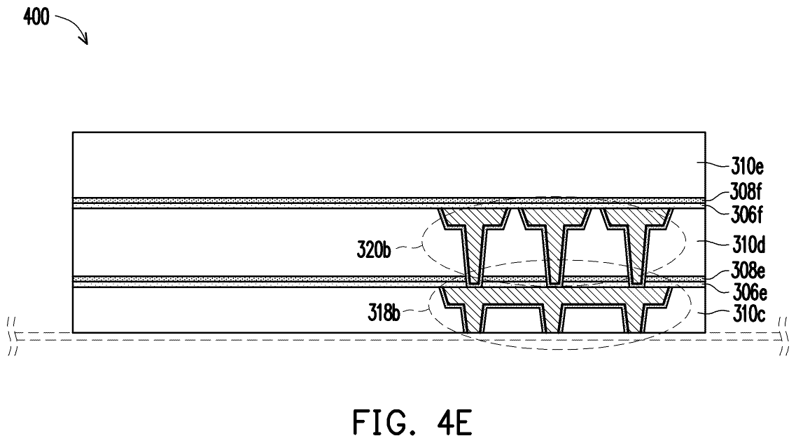

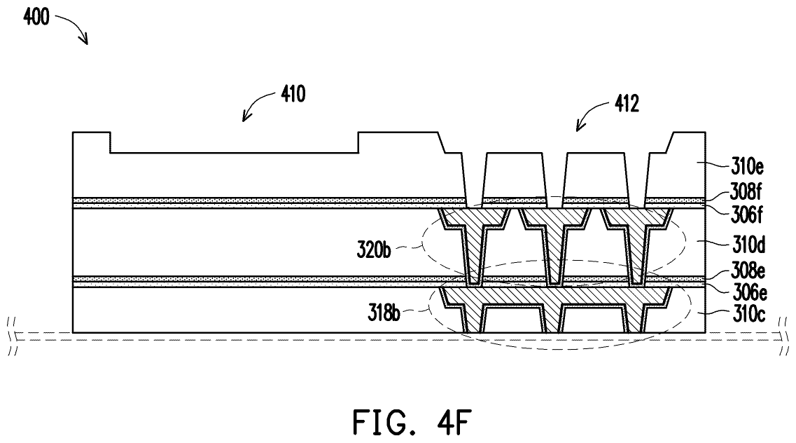

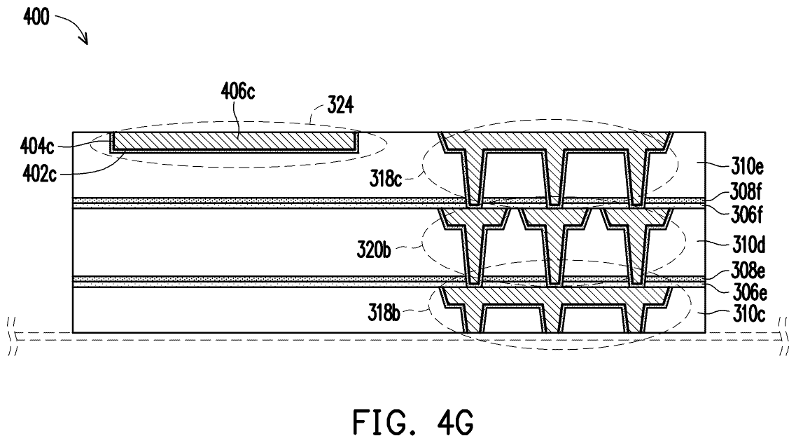

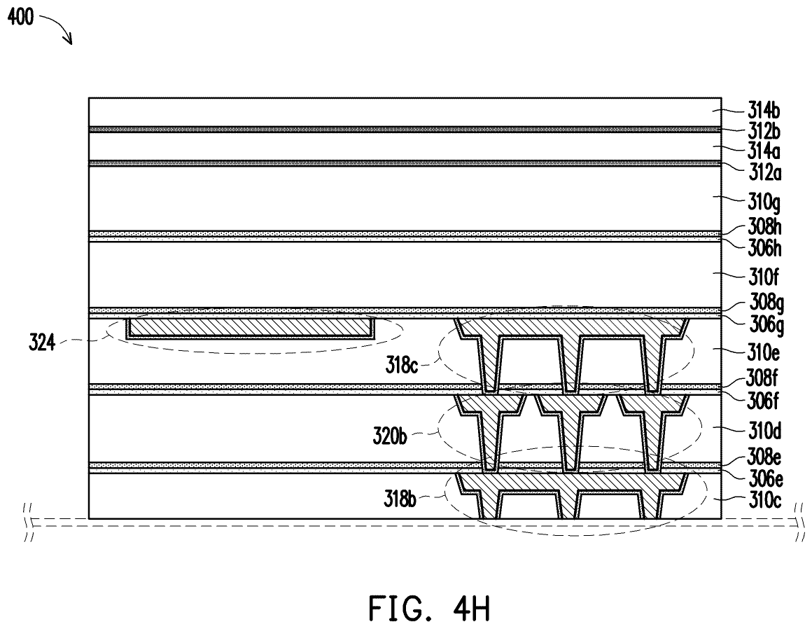

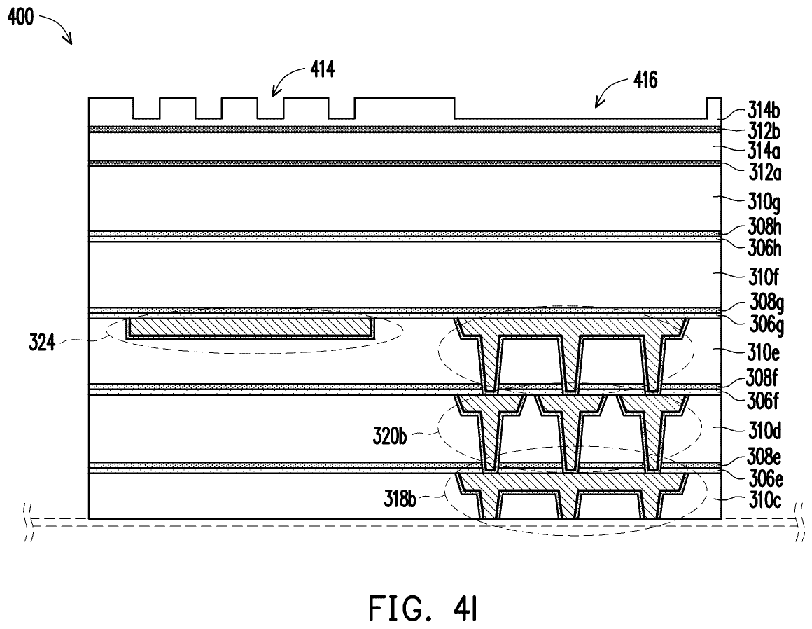

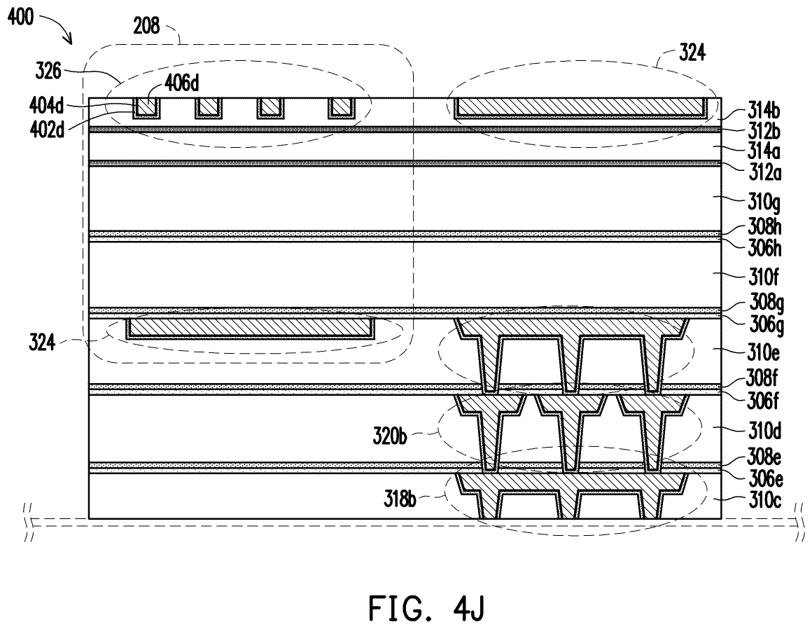

As described in greater detail in connection with FIGS. 4A-4J and elsewhere herein, the semiconductor processing tools 102-118 and/or the transport tool 120 may perform a series of semiconductor processing operations. For example, the series of semiconductor processing operations includes forming a first dielectric layer over a silicon layer. The series of semiconductor processing operations includes forming a dummy pad structure in the first dielectric layer. The series of semiconductor processing operations includes forming a second dielectric layer over the first dielectric layer. The series of semiconductor processing operations includes forming a multi-ring structure including multiple concentric rings over the dummy pad structure and in the second dielectric layer.

The number and implementation of semiconductor processing tools shown in FIG. 1 are provided as an example. In practice, there may be additional semiconductor processing tools, different semiconductor processing tools, or differently arranged semiconductor processing tools than those shown in FIG. 1. Furthermore, two or more semiconductor processing tools shown in FIG. 1 may be implemented within a single tool set, or a tool set shown in FIG. 1 may be implemented as multiple, distributed semiconductor processing tools. Additionally, or alternatively, a semiconductor processing tools of environment 100 may perform a function described as being performed by another tool set of environment 100.

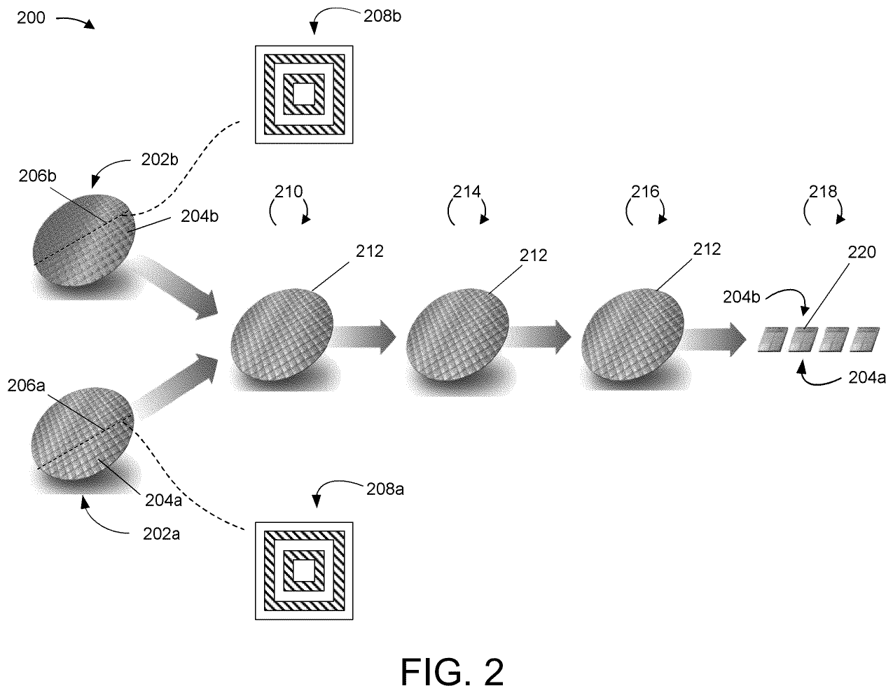

FIG. 2 is a diagram of an example implementation 200 of formation of a stacked die product described herein. The implementation 200 may correspond to a “Wafer-on-Wafer” (WoW) technique used to form a three-dimensional integrated circuit die (3DIC) product, among other examples. The example implementation 200 may use the semiconductor processing tools 102-118 and/or the transport tool 120 of FIG. 1 to form the stacked die product.

As shown, a semiconductor substrate 202a may include an integrated circuit die 204a and a semiconductor substrate 202b may include an integrated circuit die 204b. The integrated circuit dies 204a and 204b may be formed using a series of deposition operations by the deposition tool 102, a series of patterning operations by the exposure tool 104, and a series of etch operations by the etch tool 106, among other examples.

Furthermore, the semiconductor substrate 202a may include a scribe line 206a that includes a multi-layer alignment mark structure 208a. Additionally, or alternatively, the semiconductor substrate 202b may include a scribe line 206b that includes multi-layer alignment mark structure 208b. As described in greater detail in connection with FIGS. 4A-4J, the alignment mark structures 208a and 208b may be formed using a series of deposition operations by the deposition tool 102, a series of patterning operations by the exposure tool 104, and a series of etch operations by the etch tool 106, among other examples.

A bonding operation 210 (e.g., a bonding operation by the bonding tool 108, among other examples) may include aligning the semiconductor substrates 202a and 202b (and/or the integrated circuit dies 202a and 204b) using the alignment mark structures 208a and 208b. The bonding operation 210 includes bonding the semiconductor substrates 202a and 202b to form a stack of semiconductor substrates 212. As a result of the bonding operation 210, integrated circuitry of the integrated circuit dies 204a and 204b may be electrically connected for signaling purposes (e.g., inputs/output signaling, clocking or timing signaling, and/or power signaling, among other examples). The bonding operation 210 may include a eutectic bonding operation and/or another suitable type of bonding operation.

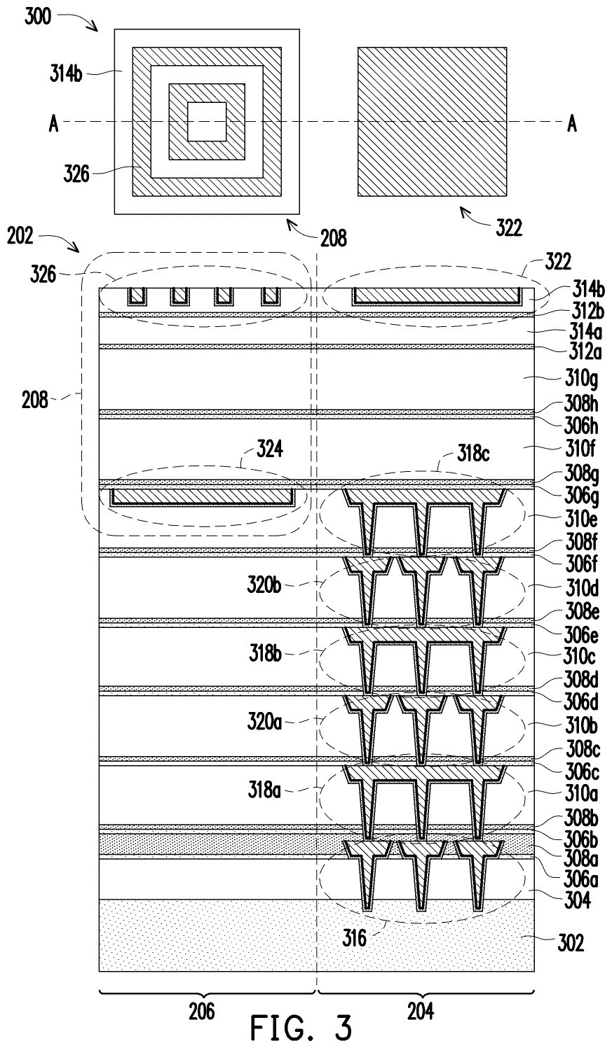

To conserve space in a final semiconductor die package, a thinning operation 214 (e.g., a thinning operation by the planarization tool 112) may be performed to a top substrate of the stack of semiconductor substrates 212 (e.g., the semiconductor substrate 202a including the integrated circuit die 204a). In some implementations, and as described in greater detail in connection with FIGS. 3-10 and elsewhere herein, a supporting sealant structure may be formed on semiconductor substrate 202a and the semiconductor substrate 202b prior to the bonding operation 210. The supporting sealant structure may improve a robustness of the stack of semiconductor substrates 212 during the thinning operation 210 and/or subsequent operations performed to the stack of semiconductor substrates 212. For example, and by improving the robustness of the stack of semiconductor substrates, a likelihood of defects and/or yield loss within the stack of semiconductor substrates 212 due to trim-loss, trim wall exposure, and/or trim peeling that is inherent to a trimming operation may be reduced. Additionally, or alternatively and in some implementations, such a trimming operation is eliminated.

A bumping operation 216 (e.g., a bumping operation by the connection tool 114, among other examples) may form connection structures (e.g., solder balls, among other examples) on pads of integrated circuit dies of a top semiconductor substrate (e.g., the integrated circuit die 204a of the semiconductor substrate 202a). Such connection structures may be used for a testing operation and/or a packaging operation that encapsulates a stacked die product (e.g., the integrated circuit die 204a joined to the integrated circuit die 204b) from the stack of semiconductor substrates 212.

A downstream series of operations 218 may include a testing operation and a dicing operation to test the stacked die product 220 and extract the stacked die product 220 from the stack of semiconductor substrates. The testing operation (e.g., a testing operation by the ATE tool 116, among other examples) may ensure a quality of the bonding operation 210 and/or a quality of the integrated circuit dies included in the stack of semiconductor substrates 212 (e.g., the integrated circuit die 202a and/or the integrated circuit die 204b, among other examples). The testing operation may include a functionality test, a parametric test, and/or a reliability test, among other examples. The dicing operation to extract the stacked die product 220 from the stack of semiconductor substrates 212 may be performed by the singulation tool 118, among other examples.

As indicated above, FIG. 2 is provided as an example. Other examples may differ from what is described with regard to FIG. 2.

FIG. 3 is a diagram 300 of an example multi-layer alignment mark structure (e.g., the multi-layer alignment mark structure 208) described herein. As shown in FIG. 3, the multi-layer alignment mark structure 208 is in the scribe line 206 of the semiconductor substrate 202 and adjacent to the integrated circuit die 204.

The semiconductor substrate 202 includes a silicon layer 302. Over the silicon layer 302, and as part of a backend of line (BEOL) layer stack in the integrated circuit die 204 (e.g., backend of line layers including a combination of dielectric layers and/or metallization layers), the semiconductor substrate 202 may include dielectric layers 304, 306a-306h, 308a-308h, and 310a-310h. One or more of the dielectric layers 304, 306a-306h, 308a-308h, and 310a-310h may be included to electrically isolate various structures of the integrated circuit die 204. Additionally, or alternatively, one or more of the dielectric layers 304, 306a-306h, 308a-308h, and 310a-310h may be configured to permit various portions of the integrated circuit die 204 (or the layers included therein) to be selectively etched or protected from etching to form one or more structures included in the integrated circuit die 204. The dielectric layers 304, 306a-306h, 308a-308h, and 310a-310h include a silicon nitride (SiₓN_{y}), an oxide (e.g., a silicon oxide (SiOₓ) and/or another oxide material), and/or another type of dielectric material.

Above the BEOL layers, and as shown in FIG. 3, the semiconductor substrate 202 includes dielectric layers 312a, 312b, 314a, and 314b. The dielectric layers 312a, 312b, 314a, and 314b may be used to form a bond interface region (e.g., a bond interface region for bonding the integrated circuit die 204 to another integrated circuit die as described in connection with FIG. 2). The dielectric layers 312a and 312b may include a silicon nitride (SiₓN_{y}), an oxide (e.g., a silicon oxide (SiOₓ) and/or another oxide material), and/or another type of dielectric material.

In some implementations, the dielectric layers 314a and 314b include a silicon oxynitride (SiON) material. In some implementations, the dielectric layer 314a corresponds to a hybrid column layer (HBC) that alleviates thermal strains and/or stresses in the bond interface region during a bonding operation. Additionally, or alternatively and in some implementations, the dielectric layer 314b corresponds to a hybrid bonding layer (HBL) that joins with another HBL of another integrated circuit die during the bonding operation. As further shown in FIG. 3, the integrated circuit die 204 includes a plurality of structures within layers formed over the silicon layer 302, including a contact structure 316, pad structures 318a-318c, columnar structures 320a and 320b, and a bond pad structure 322. The bond pad structure 322, which is part of the integrated circuit die 204, may be joined with another bond pad structure of another integrated circuit die as part of the bonding operation described in connection with FIG. 2.

As shown in FIG. 3, the multi-layer alignment mark structure 208 includes a dummy pad structure 324 below a multi-ring structure 326. The multi-ring structure 326 is above the dummy pad structure 324. The section line A-A highlights that the multi-ring structure 326 (e.g., a “bond mark”) includes concentric rings that are separate by annular regions of the dielectric layer 314b. Further, and as shown in FIG. 3, the bond pad structure 322 is included in the dielectric layer 314b adjacent to the multi-ring structure 326.

As described in greater detail in connection with FIGS. 4A-4J, the contact structure 316, the pad structures 318a-318c, the columnar structures 320a and 320b, the dummy pad structure 324, the multi-ring structure 326, and/or the bond pad structure 322 may be included in metallization layer (e.g., a copper material (Cu)) of the BEOL layers. In some implementations, the contact structure 316, the pad structures 318a-318c, the columnar structures 320a and 320b, the bond pad structure 322, and/or the multi-ring structure 326 include additional layers and/or materials used as part of a damascene operation.

In some implementations, the dummy pad structure 324 promotes a difference in a reflectance of light between the multi-ring structure 326 and the annular regions of the dielectric layer 314b, where the difference is detectable on a repeatable basis by an AOI system during an alignment operation. In some implementations, the implementation reduces a reflectance of light from the silicon layer 302.

The dummy pad structure 324 includes a contiguous, planar portion. In some implementations, an approximate area of the multi-ring structure 326 is lesser than or equal to an approximate area of the contiguous, planar portion. Additionally, or alternatively, the dummy pad structure 324 may have an approximate perimeter and the multi-ring structure 326 may be within the approximate perimeter from a top view perspective. Additionally, or alternatively and in some implementations, the dummy pad structure 324 resists a reflectance of light from the silicon layer 302. Additionally, or alternatively, an implementation may include a plurality of dielectric layers between the dummy pad structure 324 and the multi-ring structure 326 without an intervening metallization layer.

As another example, the BEOL layers may include quantity of eight metallization layers in the integrated circuit die 204, where a bottom-most metallization layer is a first metallization layer and a top-most metallization layer is an eighth metallization layer. In such a case, and as part of the implementation, the dummy pad structure 324 may be a portion of a sixth metallization layer between the first metallization layer and the eighth metallization layer. In these cases, no intervening metallization layers (e.g., no seventh or eighth metallization layers) are included in the scribe line 206 between the dummy pad structure 324 (e.g., the sixth metallization layer) and the multi-ring structure 326.

As described in connection with FIG. 3 and elsewhere herein, a semiconductor substrate (e.g., the semiconductor substrate 202) includes a scribe line (e.g., the scribe line 206). The semiconductor substrate includes a multi-layer alignment mark structure (e.g., the multi-layer alignment mark structure 208) within the scribe line that includes a multi-ring structure (e.g., the multi-ring structure 326) having concentric rings in a first dielectric layer (e.g., the dielectric layer 314b), where the concentric rings are separated by annular regions of the first dielectric layer, and a dummy pad structure (e.g., the dummy pad structure 324) in a second dielectric layer (e.g., the dielectric layer 310e) below the multi-ring structure.

As indicated above, FIG. 3 is provided as an example. Other examples may differ from what is described with regard to FIG. 3.

FIGS. 4A-4J are diagrams of an example series of semiconductor processing operations 400 used to fabricate one or more portions of a multi-layer alignment mark structure (e.g., the multi-layer alignment mark structure 208) described herein. The series of semiconductor processing operations 400 may be performed by one or more of the semiconductor processing tools 102-118 and/or the transport tool 120 described in connection with FIG. 1.

As shown in FIG. 4A, the pad structure 318b is in the dielectric layer 310c. The pad structure 318b (which may be formed using techniques described in greater detail in connection with FIGS. 4E-4G), may include a barrier layer 402a, a liner layer 404a, and a metallization layer 406a. The barrier layer 402a may include a may include tantalum (Ta), tantalum nitride (TaN), tantalum pentoxide (Ta₂O₅), titanium-tantalum alloy nitride (TaTiN), and/or titanium nitride (TiN), among other examples. The liner layer 404a may include a ruthenium material to improve copper flow when forming the metallization layer 406a.

As shown in FIG. 4B, the dielectric layers 306e, 308e, and 310d are formed on and/or over the pad structure 318b and the dielectric layer 310c. The deposition tool 102 may be used to deposit the dielectric layer 306e, 308e, and/or 310d in a PVD operation, an ALD operation, a CVD operation, an epitaxy operation, an oxidation operation, another type of deposition operation described in connection with FIG. 1, and/or another suitable deposition operation. In some implementations, the planarization tool 112 may be used to planarize the dielectric layer 306e, 308e, and/or 310d after the dielectric layer 306e, 308e, and/or 310d is deposited.

As shown in FIG. 4C, and as part of a dual damascene operation, cavities 408 are formed in the dielectric layer 310d. The dual damascene operation may be a trench-first dual damascene operation (e.g., where the trenches of the cavities 408 are formed first, and then the vias of the cavities 408 are formed through the trenches), a via-first dual damascene operation (e.g., where the vias of the cavities 408 are formed first, and then the trenches of the cavities 408 are formed above the vias), or another type of dual damascene operation. In some implementations, patterns in photoresist layers are used to etch the dielectric layer 310d to form the cavities 408. In these implementations, the deposition tool 102 may be used to form the photoresist layers on the dielectric layer 310d. The exposure tool 104 may be used to expose the photoresist layers to a radiation source to pattern the photoresist layers. A developer tool may be used to develop and remove portions of the photoresist layers to expose the patterns. The etch tool 106 may be used to etch the dielectric layer 310d based on the patterns to form the cavities 408 in the dielectric layer 310d. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 310d based on a pattern.

As shown in FIG. 4D, and as part of the dual damascene operation, the columnar structures 320b are formed in the dielectric layer 310d (e.g., formed in the cavities 408 of FIG. 4C). Forming the columnar structures 320b may include the deposition tool 102 depositing the barrier layer 402b, the liner layer 404b, and/or the metallization layer 406b in a CVD operation, a PVD operation, an ALD operation, an electroplating operation, another deposition operation described above in connection with FIG. 1, and/or another suitable deposition operation. In some implementations, the planarization tool 112 may be used to planarize the barrier layer 402b, the liner layer 404b, and/or the metallization layer 406b after the barrier layer 402b, the liner layer 404b, and/or the metallization layer 406b is deposited.

As shown in FIG. 4E, the dielectric layers 306f, 308f, and 310e are formed on and/or over the columnar structures 320b and the dielectric layer 310d. The deposition tool 102 may be used to deposit the dielectric layer 306f, 308f, and/or 310e in a PVD operation, an ALD operation, a CVD operation, an epitaxy operation, an oxidation operation, another type of deposition operation described in connection with FIG. 1, and/or another suitable deposition operation. In some implementations, the planarization tool 112 may be used to planarize the dielectric layer 306f, 308f, and/or 310e after the dielectric layer 306f, 308f, and/or 310e is deposited.

As shown in FIG. 4F, cavities 410 and 412 are formed in the dielectric layer 310e. In some implementations, patterns in photoresist layers are used to etch the dielectric layer 310e to form the cavities 410 and 412. In these implementations, the deposition tool 102 may be used to form the photoresist layers on the dielectric layer 310e. The exposure tool 104 may be used to expose the photoresist layers to a radiation source to pattern the photoresist layers. A developer tool may be used to develop and remove portions of the photoresist layers to expose the patterns. The etch tool 106 may be used to etch the dielectric layer 310e based on the patterns to form the cavities 410 and 412 in the dielectric layer 310e. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 310e based on a pattern.

As shown in FIG. 4G, the dummy pad structure 324 and the pad structure 318c are formed in the dielectric layer 310e (e.g., formed in the cavities 410 and 412 of FIG. 4F, respectively). Forming the dummy pad structure 324 and the pad structure 318c may include the deposition tool 102 depositing the barrier layer 402c, the liner layer 404c, and the metallization layer 406c in a CVD operation, a PVD operation, an ALD operation, an electroplating operation, another deposition operation described above in connection with FIG. 1, and/or another suitable deposition operation. In some implementations, the planarization tool 112 may be used to planarize the barrier layer 402c, the liner layer 404c, and/or the metallization layer 406c after the barrier layer 402c, the liner layer 404c, and/or the metallization layer 406c is deposited.

As shown in FIG. 4H, the dielectric layers 306g, 308g, 310f, 306h, 308h, 310g, 312a, 314a, 312b, and 314b are formed on and/or over the pad structure 318c, the dummy pad structure 324, and the dielectric layer 310e. The deposition tool 102 may be used to deposit the dielectric layer 306g, 308g, 310f, 306h, 308h, 310g, 312a, 314a, 312b, and/or 314b in a PVD operation, an ALD operation, a CVD operation, an epitaxy operation, an oxidation operation, another type of deposition operation described in connection with FIG. 1, and/or another suitable deposition operation. In some implementations, the planarization tool 112 may be used to planarize the dielectric layer 306g, 308g, 310f, 306h, 308h, 310g, 312a, 314a, 312b, and/or 314b after the dielectric layer 306g, 308g, 310f, 306h, 308h, 310g, 312a, 314a, 312b, and/or 314b is deposited.

As shown in FIG. 4I, and as part of a single damascene operation, cavities 414 and 416 are concurrently formed in the dielectric layer 314b. In some implementations, a pattern in a photoresist layer is used to etch the dielectric layer 314b to form the cavity 414 (e.g., for the multi-ring structure 326) and the cavity 416 (e.g., for the bond pad structure 322). In these implementations, the deposition tool 102 may be used to form the photoresist layer on the dielectric layer 314b. The exposure tool 104 may be used to expose the photoresist layer to a radiation source to pattern the photoresist layer. A developer tool may be used to develop and remove portions of the photoresist layer to expose the pattern. The etch tool 106 may be used to etch the dielectric layer 314b based on the pattern to form the cavities 414 and 416 in the dielectric layer 314b. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 314b based on a pattern.

As shown in FIG. 4J, and as part of the single damascene operation, the multi-ring structure 326 and the bond pad structure 322 are concurrently formed the dielectric layer 314b (e.g., formed in the cavities 414 and 416 of FIG. 4I). Forming the multi-ring structure 326 and the bond pad structure 322 may include the deposition tool 102 depositing the barrier layer 402d, the liner layer 404d, and the metallization layer 406d in a CVD operation, a PVD operation, an ALD operation, an electroplating operation, another deposition operation described above in connection with FIG. 1, and/or another suitable deposition operation. In some implementations, the planarization tool 112 may be used to planarize the barrier layer 402d, the liner layer 404d, and/or the metallization layer 406d after the barrier layer 402d, the liner layer 404d, and/or the metallization layer 406d is deposited.

As indicated above, FIGS. 4A-4J are provided as an example. Other examples may differ from what is described with regard to FIGS. 4A-4J.

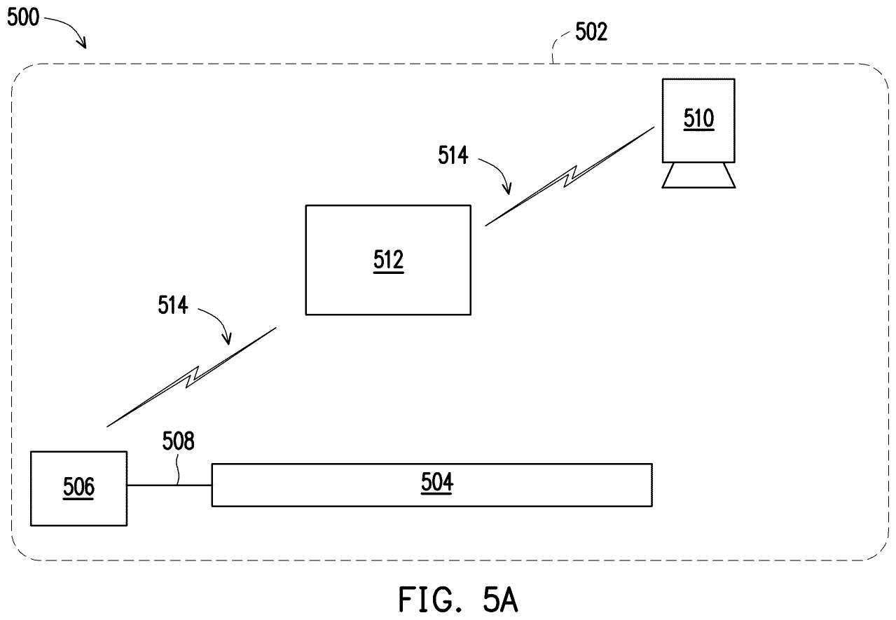

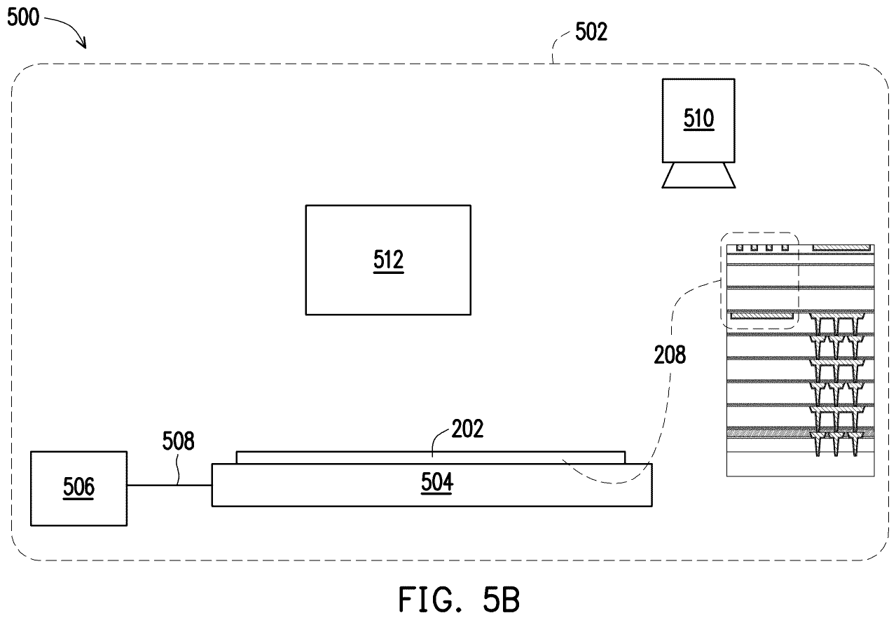

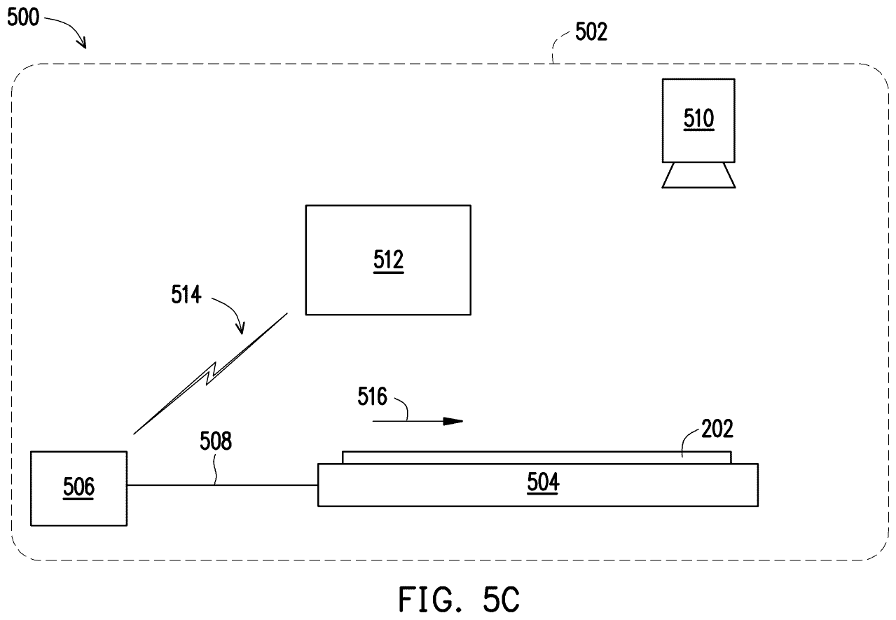

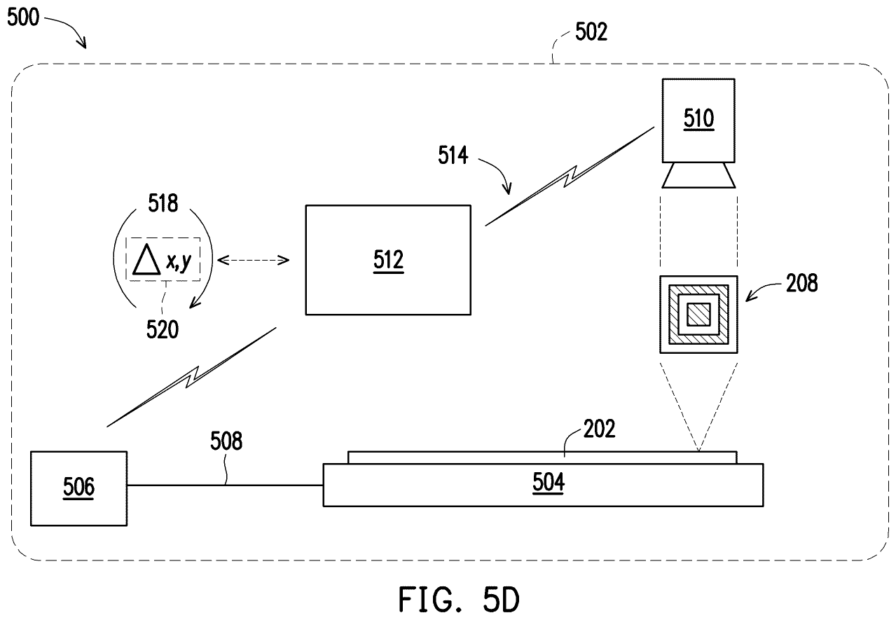

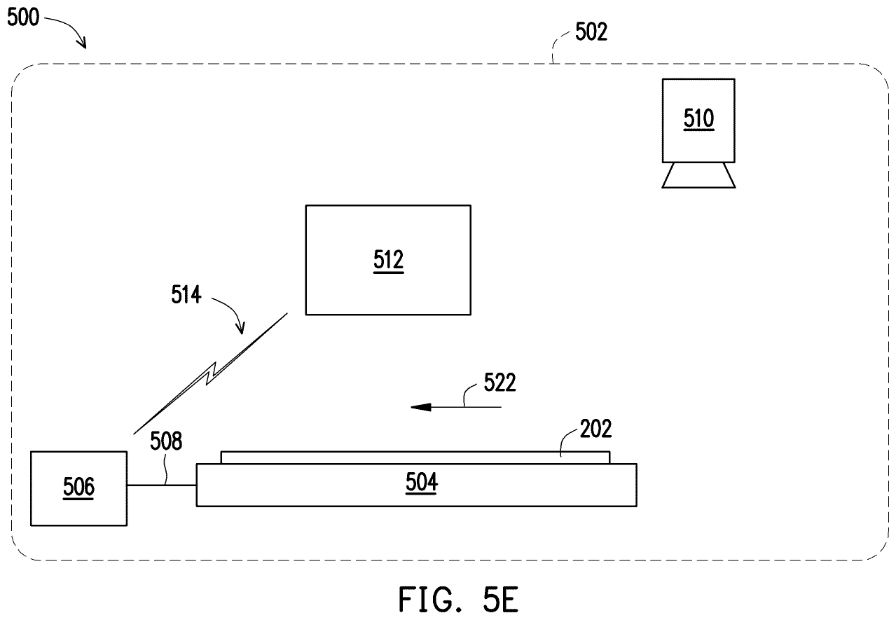

FIGS. 5A-5E are diagrams of example series of operations 500 performed by a semiconductor processing tool 502 using a multi-layer alignment mark structure (e.g., the multi-layer alignment mark structure 208) described herein. The semiconductor processing tool 502 may correspond to one or more of the semiconductor processing tools 102-120 as described in connection with FIG. 1.

As shown in FIG. 5A, the semiconductor processing tool 502 includes a carrier stage 504, a positioning system 506, and a linkage 508 that connects the carrier stage 504 and the positioning system 506. The carrier stage 504 may include an electrostatic chuck (ESC) component, a vacuum chuck component, and/or other suitable components for holding a semiconductor substrate (e.g., the semiconductor substrate 202). The positioning system 506 may include a servo motor component, a linear motor component, a linear actuator component, a pneumatic component, or another suitable component that provides a force and/or a motion for changing a position of the carrier stage 504. The linkage 508 may include a ball screw component, a linear bearing, a belt drive system, a lever, and/or other suitable components for translating a force and/or a motion from the positioning system 506 to the carrier stage 504.

The semiconductor processing tool 502 further includes an automated optical inspection (AOI) system 510. The AOI system 510 may include a camera component, a laser component, an illumination component, and/or other suitable components for detecting the multi-layer alignment mark structure.

The semiconductor processing tool 502 further includes a controller 512. The controller 512 (e.g., a processor, a combination of a processor and memory, among other examples) may communicate with the positioning system 506 and/or the AOI system 510 using one or more communication links 514. The one or more communication links 514 may include or more wireless-communication links, one or more wired-communication links, or a combination of one or more wireless-communication links and one or more wired-communication links, among other examples. In some implementations, the controller 512, the is separate from the semiconductor processing tool 502.

As shown in FIG. 5B, the semiconductor substrate 202 including the multi-layer alignment mark structure 208 is received onto the carrier stage 504. The carrier stage 504 may hold the semiconductor substrate 202 using an ESC chuck or a vacuum chuck, among other examples.

As shown in FIG. 5C, the controller 512 communicates with the positioning system 506 using the communication link(s) 514. The positioning system 506 provides a lateral motion 516 to the carrier stage 504 holding the semiconductor substrate 202 using the linkage 508.

As shown in FIG. 5D, the AOI system 510 detects the multi-layer alignment mark structure 208. Using the communication link(s) 514, the AOI system 510 may transmit a signal to the controller 512 indicating detection of the multi-layer alignment mark structure 208. Furthermore, and based on signals from the positioning system 506, the controller 512 may determine a position of the semiconductor substrate 202. Determining the position of the semiconductor substrate 202 may include determining an absolute position of the semiconductor substrate 202, a position of the semiconductor substrate 202 relative to the carrier stage 504, a position of the semiconductor substrate 202 relative to another semiconductor substrate (e.g., another semiconductor substrate to be bonded with the semiconductor substrate 202 as described in connection with FIG. 2), or a position of the semiconductor substrate 202 relative to other components of the tool (test probe components or bumping components, among other examples). In some implementations, and as shown in FIG. 5D, the controller 512 performs computations 518 that may derive a position offset 520 to be used in a subsequent semiconductor processing operation.

As shown in FIG. 5E, the controller 512 communicates with the positioning system 506. As part of performing a semiconductor processing operation, the positioning system 506 provides a lateral motion 522 to the carrier stage 504 holding the semiconductor substrate 202 using the linkage 508. The semiconductor processing operation may include a bonding operation as described in connection with FIG. 2 (e.g., the bonding operation 210). Alternatively, the semiconductor processing operation may include a probing operation, a deposition operation, or a bumping operation, among other examples.

As described in connection with FIGS. 1-5E and elsewhere herein, a semiconductor processing tool (e.g., the semiconductor processing tool 502) may perform a series of operations. The series of operations includes receiving, onto a carrier stage (e.g., the carrier stage 504), a semiconductor substrate (e.g., the semiconductor substrate 202) including a multi-layer alignment mark structure (e.g., the multi-layer alignment mark structure 208), where the multi-layer alignment mark structure includes concentric metal rings (e.g., the multi-ring structure 326) interspersed with annular regions of a first dielectric layer (e.g., the dielectric layer 314b), and where the multi-layer alignment mark structure includes a dummy pad structure (e.g., the pad structure 318c) in a second dielectric layer (e.g., the dielectric layer 310e) that is below the concentric metal rings. The series of operations includes detecting the multi-layer alignment mark structure. The series of operations includes determining a position of the semiconductor substrate using the multi-layer alignment mark structure. The series of operations includes performing a semiconductor processing operation based on the position.

As indicated above, FIGS. 5A-5E are provided as an example. Other examples may differ from what is described with regard to FIGS. 5A-5E.

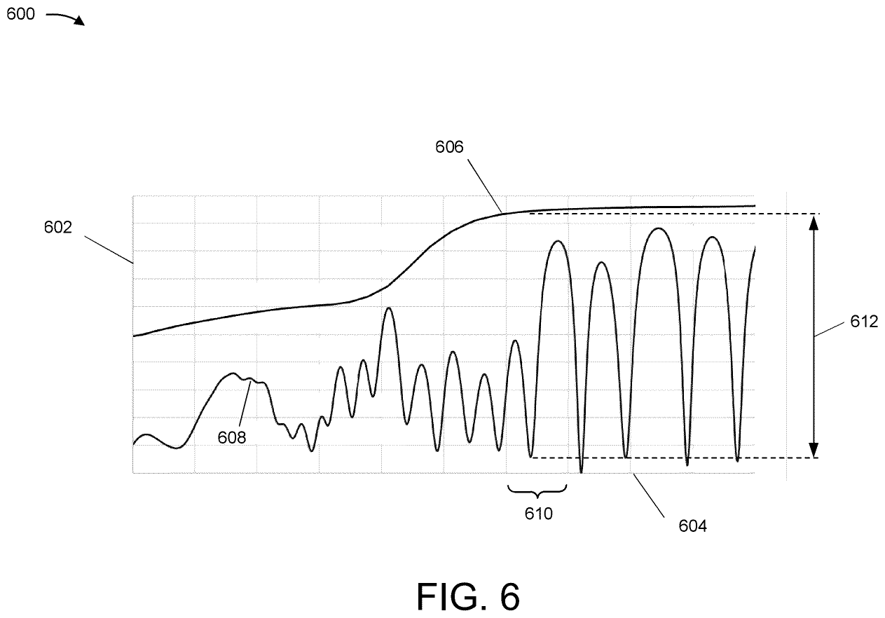

FIG. 6 is a diagram of example reflectance data 600 for materials included in a multi-layer alignment mark structure (e.g., the multi-layer alignment mark structure 208) described herein. The reflectance data 600 shows ratios of amounts of light reflected by materials within the multi-layer alignment mark structure relative to amounts of light incident on the materials. In other words, the reflectance data 600 is a measure of how much light is reflected by the materials compared to how much light the materials absorb or transmit.

The reflectance data 600 shows the ratio 602 versus a wavelength of incident light 604. The reflectance data 600 includes first data 606 that may correspond to a metal material included in a multi-ring structure of a multi-layer alignment mark structure and/or a dummy pad structure included in the multi-layer alignment mark structure (e.g., a Cu material included in the multi-ring structure 326 and/or the pad structure 318c of the multi-layer alignment mark structure 208). The reflectance data 600 further includes second data 608 that may correspond to a dielectric material included in annular regions between rings of the multi-ring structure (e.g., an SiON material included in the dielectric layer 314b)

As shown in FIG. 6, and for a range of wavelengths 610 of incident light, a difference 612 between the ratio 602 (e.g., the reflectance) for the first data 606 (e.g., the Cu material) and the ratio 602 for the second data 608 (e.g., the SiON material) may be greater relative to the difference 612 for other ranges of wavelengths. In other words, an optical contrast between the materials may be greater relative to optical contrasts for other ranges of wavelengths. Additionally, or alternatively and in the context of a multi-layer alignment mark structure (e.g., the multi-layer alignment mark structure 208), a reflectance of light from annular regions of a dielectric layer (e.g., annular regions of the dielectric layer 314b) may be lesser relative to a reflectance of the light from concentric metal rings (e.g., the multi-ring structure 326).

As an example, the range of wavelengths of the 610 may be included in range of approximately 640 nanometers to approximately 680 nanometers. Selecting a wavelength of at least 640 nanometers may allow for sufficient absorption of the incident light by the material associated with the second data 608 a lesser wavelength may result in an amount of light being reflect by the material that lessens a contrast with the material associated with the first data 606. Selecting a wavelength of no more than 680 nanometers may allow for sufficient reflection of the incident light from the material associated with the first data 606; a larger wavelength may lessen control and/or repeatability related to measurements made by an AOI system (e.g., the AOI system 510). However, other values for the range of wavelengths 610, as well as materials corresponding to the first data 606 and the second data 608, are within the scope of the present disclosure.

As indicated above, FIG. 6 is provided as an example. Other examples may differ from what is described with regard to FIG. 6.

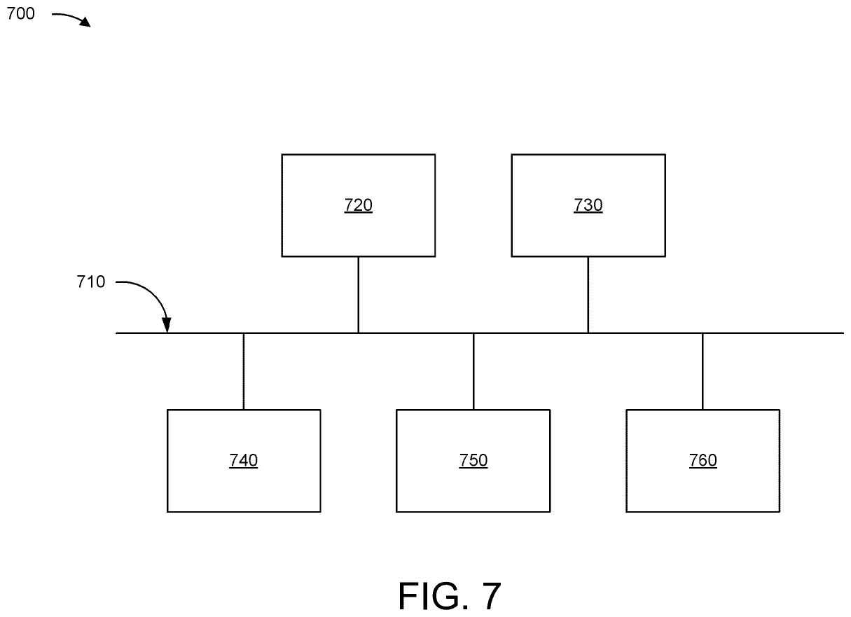

FIG. 7 is a diagram of example components of a device 700 that may use a multi-layer alignment mark structure (e.g., the multi-layer alignment mark structure 208) for an alignment operation. The device 700 may correspond to one or more of the semiconductor processing tools 102-120, the semiconductor processing tool 502, the positioning system 506, the AOI system 510, and/or the controller 512. In some implementations, the semiconductor processing tools 102-120, the semiconductor processing tool 502, the positioning system 506, the AOI system 510, and/or the controller 512 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and implementation of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

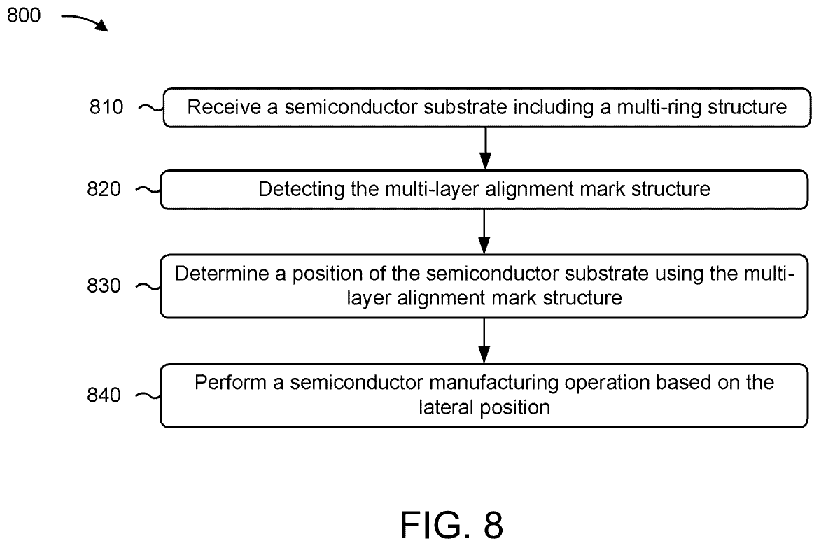

FIG. 8 is a flowchart of an example process 800 associated with using a multi-layer alignment mark structure. In some implementations, one or more process blocks of FIG. 8 are performed by a semiconductor processing tool (e.g., one or more of the semiconductor processing tools 102-120 1 and/or the semiconductor processing tool 502). In some implementations, one or more process blocks of FIG. 8 are performed by another device or a group of devices separate from or including the semiconductor processing tool (e.g., the positioning system 506, the AOI system 510, and/or the controller 512). Additionally, or alternatively, one or more process blocks of FIG. 8 may be performed by one or more components of device 700, such as processor 720, memory 730, input component 740, output component 750, and/or communication component 760.

As shown in FIG. 8, process 800 may include receiving, onto a carrier stage, a semiconductor substrate including a multi-layer alignment mark structure, wherein the multi-layer alignment mark structure includes concentric metal rings interspersed with annular regions of a first dielectric layer, and wherein the multi-layer alignment mark structure includes a dummy pad structure in a second dielectric layer that is below the concentric metal rings (block 810). For example, a semiconductor processing tool (e.g., the semiconductor processing tool 502) may receive, onto a carrier stage (e.g., the carrier stage 504), a semiconductor substrate (e.g., the semiconductor substrate 202) including a multi-layer alignment mark structure (e.g., the multi-layer alignment mark structure 208), as described above. In some implementations, the multi-layer alignment mark structure includes concentric metal rings (e.g., the multi-ring structure 326) interspersed with annular regions of a first dielectric layer (e.g., annular regions of the dielectric layer 314b). In some implementations, the multi-layer alignment mark structure includes a dummy pad structure (e.g., the pad structure 318c) in a second dielectric layer (e.g., the dielectric layer 310e) that is below the concentric metal rings.

As further shown in FIG. 8, process 800 may include detecting the multi-layer alignment mark structure (block 820). For example, the semiconductor processing tool may detect the multi-layer alignment mark structure, as described above.

As further shown in FIG. 8, process 800 may include determining a position of the semiconductor substrate using the multi-layer alignment mark structure (block 830). For example, the semiconductor processing tool may determine a position of the semiconductor substrate using the multi-layer alignment mark structure, as described above.

As further shown in FIG. 8, process 800 may include performing a semiconductor processing operation based on the position (block 840). For example, the semiconductor processing tool may perform a semiconductor processing operation based on the position, as described above.

Process 800 may include additional implementations, such as any single implementation or any combination of implementations described below and/or in connection with one or more other processes described elsewhere herein.

In a first implementation, detecting the multi-layer alignment mark structure includes projecting light having a wavelength that is included in a range of approximately 640 nanometers to approximately 680 nanometers onto the multi-layer alignment mark structure, and detecting the multi-layer alignment mark structure based on a difference between reflectance of the light from the concentric metal rings and the annular regions of the first dielectric layer.

In a second implementation, alone or in combination with the first implementation, a reflectance of the light from the annular regions is lesser relative to a reflectance of the light from the concentric metal rings.

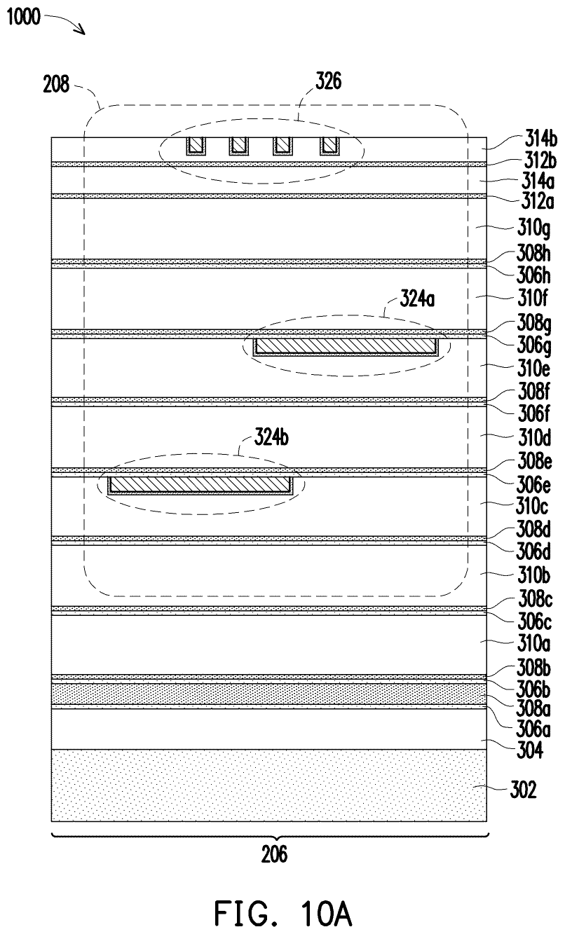

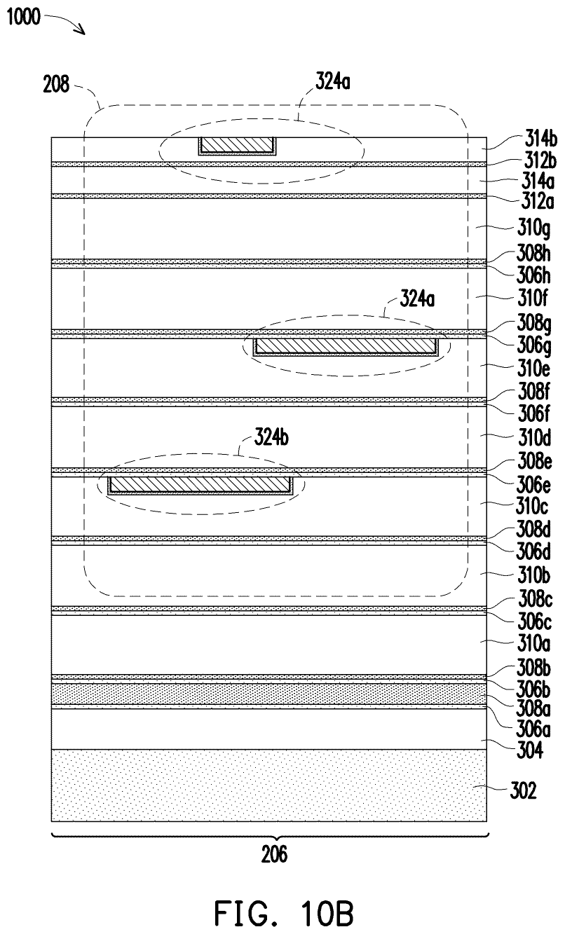

In a third implementation, alone or in combination with one or more of the first and second implementations, the dummy pad structure is a first dummy pad structure (e.g., the dummy pad structure 324a of FIG. 10A) and the multi-layer alignment mark structure further includes a second dummy pad structure (e.g., the dummy pad structure 324b of FIG. 10A) in a third dielectric layer (e.g., the dielectric layer 310c) below the first dummy pad structure.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

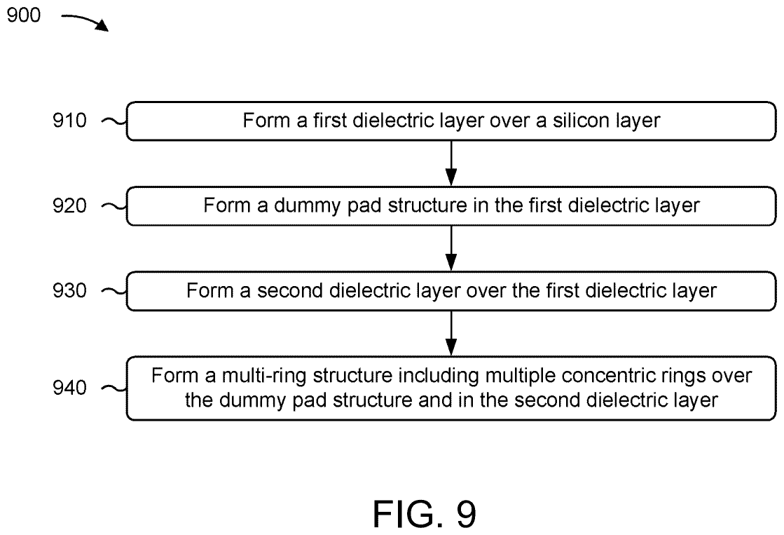

FIG. 9 is a flowchart of an example process 900 associated with a multi-layer alignment mark structure. In some implementations, one or more process blocks of FIG. 9 are performed using one or more semiconductor processing tools (e.g., one or more of the semiconductor processing tools 102-118). Additionally, or alternatively, one or more process blocks of FIG. 9 may be performed using one or more components of device 700, such as processor 720, memory 730, input component 740, output component 750, and/or communication component 760.

As shown in FIG. 9, process 900 may include forming a first dielectric layer over a silicon layer (block 910). For example, one or more of the semiconductor processing tools 102-118 may be used to form a first dielectric layer (e.g., the dielectric layer 310e) over a silicon layer (e.g., the silicon layer 302), as described herein.

As further shown in FIG. 9, process 900 may include forming a dummy pad structure in the first dielectric layer (block 920). For example, one or more of the semiconductor processing tools 102-118 may be used to form a dummy pad structure (e.g., the pad structure 318c) in the first dielectric layer, as described herein.

As further shown in FIG. 9, process 900 may include forming a second dielectric layer over the first dielectric layer (block 930). For example, one or more of the semiconductor processing tools 102-118 may be used to form a second dielectric layer (e.g., the dielectric layer 314b) over the first dielectric layer, as described herein.

As further shown in FIG. 9, process 900 may include forming a multi-ring structure including multiple concentric rings over the dummy pad structure and in the second dielectric layer (block 940). For example, one or more of the semiconductor processing tools 102-118 may be used to form a multi-ring structure (e.g., the multi-ring structure 326) including multiple concentric rings over the dummy pad structure and in the second dielectric layer, as described herein.

Process 900 may include additional implementations, such as any single implementation or any combination of implementations described below and/or in connection with one or more other processes described elsewhere herein.

In a first implementation, forming the dummy pad structure includes forming a contiguous, planar portion having a first approximate area, and where forming the multi-ring structure includes forming the multi-ring structure to have a second approximate area that is lesser than or equal to the first approximate area.

In a second implementation, alone or in combination with the first implementation, forming the dummy pad structure includes forming a contiguous, planar portion, and where forming the multi-ring structure includes forming the multi-ring structure within a perimeter of a top view of the contiguous, planar portion.

In a third implementation, alone or in combination with one or more of the first and second implementations, forming the dummy pad structure includes forming the dummy pad structure using a dual damascene technique.

In a fourth implementation, alone or in combination with one or more of the first through third implementations, forming the multi-ring structure includes forming the multi-ring structure using a single damascene technique.

In a fifth implementation, alone or in combination with one or more of the first through fourth implementations, process 900 includes forming a bond pad structure (e.g., the bond pad structure 322) in the second dielectric layer simultaneously with the multi-ring structure using the single damascene technique.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

FIGS. 10A and 10B are diagrams of example implementations 1000 of a multi-layer alignment mark structure described herein. The implementations 1000 of FIGS. 10A and 10B may include one or more aspects of the multi-layer alignment mark structure 208 described in connection with FIGS. 1-9.

As shown in the implementation 1000 of FIG. 10A, the multi-layer alignment mark structure 208 includes the dummy pad structure 324a and the dummy pad structure 324b (e.g., multiple dummy pad structures). Based on reflective and/or refractive properties of materials within the scribe line 206, the multi-layer the dummy pad structure 324a and/or the dummy pad structure 324b may be offset from a central axis of the multi-ring structure 326. Furthermore, the dummy pad structure 324a and the dummy pad structure 324b may be offset from one another.

In some implementations, a metallization layer of a dummy pad structure (e.g., the dummy pad structure 324a and/or the dummy pad structure 324b) may be selected based on the reflective and/or refractive properties of materials within the scribe line. For example, and as shown in FIG. 10A, the dummy pad structure 324a is formed using a sixth metallization layer (e.g., an “M6” metallization layer) and the dummy pad structure 324b is formed using a fourth metallization layer (e.g., an “M4” metallization layer).

As shown in the implementation 1000 of FIG. 10B, the multi-layer alignment mark structure 208 includes a combination of dummy pad structures 324a-324b interspersed throughout layers within in the scribe line 206 (e.g., the multi-layer alignment mark structure 208 excludes the multi-ring structure 326). In addition to lateral locations that may be offset with one another, each of the dummy pad structures 324a-324b may be a different, respective width.

The number and arrangement of structures shown in FIGS. 10A and 10B are provided as one or more examples. In practice, the multi-layer alignment mark structure 208 may include different combinations of structures (e.g., different combinations of the multi-ring structure 326 and/or the dummy pad structure 324), or differently arranged structures than those shown in FIGS. 10A and 10B (e.g., the multi-ring structure 326 and/or the dummy pad structure(s) 324 may be in different metallization layers than those shown in FIGS. 10A and 10B).

Some implementations herein provide a semiconductor substrate including a multi-layer alignment mark structure and methods of formation. The multi-layer alignment mark structure may include concentric rings (e.g., a multi-ring bond mark structure) and a dummy pad structure below the concentric rings. For a light source of a given wavelength, the dummy pad structure may create an optical contrast between the concentric rings and annular regions of a dielectric region in which the concentric rings are formed. The optical contrast may improve a detectability of the multi-layer alignment mark structure by an AOI system relative to another alignment mark structure not including the dummy pad structure.

In this way, an efficiency of a semiconductor processing tool including the AOI system is increased. By increasing the efficiency of the semiconductor processing tool, an amount of resources needed to fabricate a volume of semiconductor substrates including the multi-layer alignment mark structure (e.g., a quantity of the semiconductor processing tool, labor, and/or computing resources) is reduced.

As described in greater detail above, some implementations described herein provide a semiconductor substrate. The semiconductor substrate includes a scribe line. The semiconductor substrate includes a multi-layer alignment mark structure within the scribe line that includes a multi-ring structure having concentric rings in a first dielectric layer, where the concentric rings are separated by annular regions of the first dielectric layer, and a dummy pad structure in a second dielectric layer below the multi-ring structure.

As described in greater detail above, some implementations described herein provide a method. The method includes receiving, onto a carrier stage, a semiconductor substrate including a multi-layer alignment mark structure, where the multi-layer alignment mark structure includes concentric metal rings interspersed with annular regions of a first dielectric layer, and where the multi-layer alignment mark structure includes a dummy pad structure in a second dielectric layer that is below the concentric metal rings. The method includes detecting the multi-layer alignment mark structure. The method includes determining a position of the semiconductor substrate using the multi-layer alignment mark structure. The method includes performing a semiconductor processing operation based on the position.

As described in greater detail above, some implementations described herein provide a method. The method includes forming a first dielectric layer over a silicon layer. The method includes forming a dummy pad structure in the first dielectric layer. The method includes forming a second dielectric layer over the first dielectric layer. The method includes forming a multi-ring structure including multiple concentric rings over the dummy pad structure and in the second dielectric layer.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor substrate comprising:
a scribe line; and
a multi-layer alignment mark structure within the scribe line comprising:
a multi-ring structure having concentric rings in a first dielectric layer,
wherein the concentric rings are separated by annular regions of the first dielectric layer; and
a dummy pad structure in a second dielectric layer below the multi-ring structure.

2. The semiconductor substrate of claim 1, wherein the dummy pad structure promotes a difference in a reflectance of light between the concentric rings and the annular regions, and
wherein the difference in the reflectance of light is detectable on a repeatable basis by an automated optical inspection system.

3. The semiconductor substrate of claim 1, wherein the dummy pad structure resists a reflectance of light from a silicon layer that is below the multi-layer alignment mark structure.

4. The semiconductor substrate of claim 1, wherein the multi-ring structure and the dummy pad structure each comprise:
a copper material.

5. The semiconductor substrate of claim 1, wherein a location of the dummy pad structure is offset from a central axis of the multi-ring structure.

6. The semiconductor substrate of claim 1, wherein the dummy pad structure is included in a metallization layer included in a stack of backend of line layers.

7. The semiconductor substrate of claim 6, wherein the stack of backend of line layers includes a quantity of eight metallization layers,
wherein a bottom-most metallization layer is a first metallization layer,
wherein a top-most metallization layer is an eighth metallization layer,
wherein the dummy pad structure is a portion of a sixth metallization layer between the first metallization layer and the eighth metallization layer.

8. The semiconductor substrate of claim 1, further comprising:
a plurality of dielectric layers between the dummy pad structure and the multi-ring structure without an intervening metallization layer between the dummy pad structure and the multi-ring structure.

9. The semiconductor substrate of claim 1, wherein the dummy pad structure is a first dummy pad structure and further comprising:
a second dummy pad structure below the first dummy pad structure.

10. The semiconductor substrate of claim 1, further comprising:
a bond pad structure in an integrated circuit die adjacent to the multi-ring structure.

11. The semiconductor substrate of claim 10, wherein the bond pad structure is in a same dielectric layer as the multi-ring structure.

12. A method, comprising:
receiving, onto a carrier stage, a semiconductor substrate including a multi-layer alignment mark structure,
wherein the multi-layer alignment mark structure includes concentric metal rings interspersed with annular regions of a first dielectric layer, and
wherein the multi-layer alignment mark structure includes a dummy pad structure in a second dielectric layer that is below the concentric metal rings;
detecting the multi-layer alignment mark structure;
determining a position of the semiconductor substrate using the multi-layer alignment mark structure; and
performing a semiconductor processing operation based on the position.

13. The method of claim 12, wherein detecting the multi-layer alignment mark structure comprises:
projecting light having a wavelength that is included in a range of approximately 640 nanometers to approximately 680 nanometers onto the multi-layer alignment mark structure, and
detecting the multi-layer alignment mark structure based on a difference between reflectance of the light from the concentric metal rings and the annular regions of the first dielectric layer.

14. The method of claim 13, wherein a reflectance of the light from the annular regions is lesser relative to a reflectance of the light from the concentric metal rings.

15. The method of claim 12, wherein the dummy pad structure is a first dummy pad structure and the multi-layer alignment mark structure further comprises:
a second dummy pad structure in a third dielectric layer below the first dummy pad structure.

16. A method, comprising:
forming a first dielectric layer over a silicon layer;
forming a dummy pad structure in the first dielectric layer;
forming a second dielectric layer over the first dielectric layer; and
forming a multi-ring structure including multiple concentric rings over the dummy pad structure and in the second dielectric layer.

17. The method of claim 16, wherein forming the dummy pad structure comprises forming a contiguous, planar portion having a first approximate area, and wherein forming the multi-ring structure comprises:
forming the multi-ring structure to have a second approximate area that is lesser than or equal to the first approximate area.

18. The method of claim 16, wherein forming the dummy pad structure comprises forming a contiguous, planar portion and wherein forming the multi-ring structure comprises:
forming the multi-ring structure within a perimeter of a top view of the contiguous, planar portion.

19. The method of claim 16, wherein forming the multi-ring structure comprises:
forming the multi-ring structure using a single damascene technique.

20. The method of claim 19, further comprising:
forming a bond pad structure in the second dielectric layer simultaneously with the multi-ring structure using the single damascene technique.
